(19) United States
(12) Patent Application Publication
(10) Pub. No.: US 2026/0156917 A1
(43) Pub. Date: Jun. 4, 2026

(54) SEMICONDUCTOR DEVICE

(71) Applicant: Nuvoton Technology Corporation Japan, Kyoto (JP)

(72) Inventors: Yusuke NAKAYAMA, Kyoto (JP); Masahide TAGUCHI, Kyoto (JP); Akira KIMURA, Kyoto (JP)

(21) Appl. No.: 19/455,163

(22) Filed: Jan. 21, 2026

Related U.S. Application Data
(63) Continuation of application No. PCT/JP2024/038181, filed on Oct. 25, 2024.
(60) Provisional application No. 63/593,446, filed on Oct. 26, 2023.

(51) Int. Cl. H10D 84/00

(52) U.S. Cl. CPC H10D 84/146

(57) ABSTRACT

A semiconductor device that is a square in a plan view, the semiconductor device including: a vertical MOS transistor; and a Schottky barrier diode in which the semiconductor layer functions as an anode or a cathode. The semiconductor device further includes: a first pad that is a portion of an upper surface of the semiconductor device; a second pad that is a portion of the upper surface; a third pad that is a portion of the upper surface; and a fourth pad that is a portion of the upper surface, the first pad to the fourth pad being circles each having an equal diameter. In the plan view, centers of the first pad and the third pad are located on one diagonal line of the semiconductor device, and centers of the second pad and the fourth pad are located on an other diagonal line of the semiconductor device.

### CROSS REFERENCE TO RELATED APPLICATIONS

This is a continuation application of PCT International Patent Application No. PCT/JP2024/038181 filed on Oct. 25, 2024, designating the United States of America, which is based on and claims priority of U.S. Provisional Patent Application No. 63/593446 filed on Oct. 26, 2023. The entire disclosures of the above-identified applications, including the specifications, drawings and claims are incorporated herein by reference in their entirety.

### FIELD

The present disclosure relates to semiconductor devices.

### BACKGROUND

Conventionally, commercially available semiconductor devices have been those in each of which a metal-oxide-semiconductor (MOS) transistor and a Schottky barrier diode are molded in one package to allow each of the MOS transistor and the Schottky barrier diode to function as an independent element.

### CITATION LIST

### Patent Literature

PTL 1: Japanese Unexamined Patent Application Publication No. 2002-203966

### SUMMARY

### Technical Problem

Each of the above-described commercially available semiconductor devices has a size of at least 2.0 mm×2.0 mm in a plan view of the semiconductor device.

On the other hand, there has been a demand for mounting electronic components within a limited space at a high density.

In view of this, the present disclosure provides a semiconductor device that includes a MOS transistor and a Schottky barrier diode each of which functions as an independent element and that makes it possible to reduce its size in a plan view more than ever before.

### Solution to Problem

A semiconductor device according to one aspect of the present disclosure is a chip-size-package type semiconductor device, the semiconductor device including: a semiconductor layer that includes a semiconductor substrate of a first conductivity type and a low-concentration impurity layer of the first conductivity type, the semiconductor substrate containing an impurity having a first concentration, the low-concentration impurity layer being provided on an upper surface of the semiconductor substrate and containing an impurity having a second concentration lower than the first concentration; a vertical metal-oxide-semiconductor (MOS) transistor that is provided in the semiconductor layer; and a Schottky barrier diode in which the low-concentration impurity layer functions as a cathode when the first conductivity type is N type, and functions as an anode when the first conductivity type is P type. The semiconductor device further includes: a first pad that is a portion of an upper surface of the semiconductor device and functions as a source pad of the vertical MOS transistor; a second pad that is a portion of the upper surface of the semiconductor device, functions as a drain pad of the vertical MOS transistor, functions as a cathode pad of the Schottky barrier diode when the first conductivity type is the N type, and functions as an anode pad of the Schottky barrier diode when the first conductivity type is the P type; a third pad that is a portion of the upper surface of the semiconductor device, functions as the anode pad of the Schottky barrier diode when the first conductivity type is the N type, and functions as the cathode pad of the Schottky barrier diode when the first conductivity type is the P type; and a fourth pad that is a portion of the upper surface of the semiconductor device and functions as a gate pad of the vertical MOS transistor. In a plan view of the semiconductor device: the semiconductor device is a square including a first vertex, a second vertex, a third vertex, and a fourth vertex in a counterclockwise direction; the first pad, the second pad, the third pad, and the fourth pad are circles each having an equal diameter; a center of the first pad and a center of the third pad are located on a first diagonal line connecting the first vertex and the third vertex; a center of the second pad and a center of the fourth pad are located on a second diagonal line connecting the second vertex and the fourth vertex; and a distance between a center of the semiconductor device and the center of the first pad, a distance between the center of the semiconductor device and the center of the second pad, a distance between the center of the semiconductor device and the center of the third pad, and a distance between the center of the semiconductor device and the center of the fourth pad are equal.

### Advantageous Effects

A semiconductor device according to one aspect of the present disclosure includes a MOS transistor and a Schottky barrier diode each of which functions as an independent element, and makes it possible to reduce its size in a plan view more than ever before.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a planar schematic diagram showing an example of a structure of a semiconductor device according to an embodiment.

FIG. 2 is a cross-sectional schematic diagram showing an example of the structure of the semiconductor device according to the embodiment.

FIG. 3A is a circuit diagram of the semiconductor device according to the embodiment when a first conductivity type is N type.

FIG. 3B is a circuit diagram of the semiconductor device according to the embodiment when the first conductivity type is P type.

FIG. 4 is a comparative chart that compares the conduction resistance of a vertical MOS transistor according to a comparative example and the conduction resistance of a vertical MOS transistor according to the embodiment.

FIG. 5 is a correlation diagram schematically showing a relationship between the type of metal material included in a Schottky contact surface and the characteristics of a Schottky barrier diode when the first conductivity type is the N type.

FIG. 6 is a planar schematic diagram showing another example of a structure of the semiconductor device according to the embodiment.

FIG. 7 is a planar schematic diagram showing an example of a structure of a semiconductor device according to Variation 1.

FIG. 8 is a planar schematic diagram showing an example of a structure of a semiconductor device according to Variation 2.

### DESCRIPTION OF EMBODIMENT

### Circumstances Leading to One Aspect of the Present Disclosure

A conventional semiconductor device in which a MOS transistor and a Schottky barrier diode are molded in one package to allow each of the MOS transistor and the Schottky barrier diode to function as an independent element includes, on a mounting surface at which the conventional semiconductor device is mounted on, for example, a mounting substrate, a total of at least five terminals that are three terminals connected to the gate, the source, and the drain of the MOS transistor, respectively, and two terminals connected to the anode and the cathode of the Schottky barrier diode, respectively.

In view of this, the inventors acquired the knowledge that it is possible to set the number of terminals of the above-described semiconductor device at four by consolidating, into one terminal, the terminal connected to the drain of the MOS transistor and the terminal connected to the anode of the Schottky barrier diode or the terminal connected to the cathode of the Schottky barrier diode when the above-described semiconductor device is applied to a case in which the drain of the MOS transistor and the anode or the cathode of the Schottky barrier diode are directly connected.

The inventors conducted extensive experiments and studies based on the knowledge to arrive at a semiconductor device according to the present disclosure.

A semiconductor device according to the present disclosure is a chip-size-package type semiconductor device, the semiconductor device including: a semiconductor layer that includes a semiconductor substrate of a first conductivity type and a low-concentration impurity layer of the first conductivity type, the semiconductor substrate containing an impurity having a first concentration, the low-concentration impurity layer being provided on an upper surface of the semiconductor substrate and containing an impurity having a second concentration lower than the first concentration; a vertical metal-oxide-semiconductor (MOS) transistor that is provided in the semiconductor layer; and a Schottky barrier diode in which the low-concentration impurity layer functions as a cathode when the first conductivity type is N type, and functions as an anode when the first conductivity type is P type. The semiconductor device further includes: a first pad that is a portion of an upper surface of the semiconductor device and functions as a source pad of the vertical MOS transistor; a second pad that is a portion of the upper surface of the semiconductor device, functions as a drain pad of the vertical MOS transistor, functions as a cathode pad of the Schottky barrier diode when the first conductivity type is the N type, and functions as an anode pad of the Schottky barrier diode when the first conductivity type is the P type; a third pad that is a portion of the upper surface of the semiconductor device, functions as the anode pad of the Schottky barrier diode when the first conductivity type is the N type, and functions as the cathode pad of the Schottky barrier diode when the first conductivity type is the P type; and a fourth pad that is a portion of the upper surface of the semiconductor device and functions as a gate pad of the vertical MOS transistor. In a plan view of the semiconductor device: the semiconductor device is a square including a first vertex, a second vertex, a third vertex, and a fourth vertex in a counterclockwise direction; the first pad, the second pad, the third pad, and the fourth pad are circles each having an equal diameter; a center of the first pad and a center of the third pad are located on a first diagonal line connecting the first vertex and the third vertex; a center of the second pad and a center of the fourth pad are located on a second diagonal line connecting the second vertex and the fourth vertex; and a distance between a center of the semiconductor device and the center of the first pad, a distance between the center of the semiconductor device and the center of the second pad, a distance between the center of the semiconductor device and the center of the third pad, and a distance between the center of the semiconductor device and the center of the fourth pad are equal.

The semiconductor device thus configured is an unmolded chip-size-package type semiconductor device in which a vertical MOS transistor and a Schottky barrier diode each function as an independent element and that includes four pads, that is, four terminals on an upper surface that is a mounting surface at which the unmolded chip-size-package type semiconductor device is mounted on, for example, a mounting substrate.

Accordingly, the semiconductor device thus configured makes it possible to reduce its size in a plan view, compared to a conventional semiconductor device in which a MOS transistor and a Schottky barrier diode are molded in one package to allow each of the MOS transistor and the Schottky barrier diode to function as an independent element and that includes at least five terminals on a mounting surface.

As stated above, the semiconductor device thus configured includes a MOS transistor and a Schottky barrier diode each of which functions as an independent element, and makes it possible to reduce its size in a plan view more than ever before.

It should be noted that, in the Description, with regard to a structure whose shape in a plan view is a square or a rectangle such as a semiconductor device, a center in the plan view refers to an intersection point of the diagonal lines in the square or the rectangle; with regard to a structure whose shape in the plan view is a circle such as the first pad to the fourth pad, a center in the plan view refers to the center of the circle; with regard to a structure whose shape in the plan view is an oblong, a center in the plan view refers to an intersection point of an axis of symmetry extending in the longer-side direction of the oblong and an axis of symmetry extending in the shorter-side direction of the oblong; and with regard to a structure whose shape in the plan view is an ellipse, a center in the plan view refers to an intersection point of the long axis and the short axis of the ellipse.

Moreover, in the plan view of the semiconductor device, when an area of the semiconductor device is equally divided by four square regions that do not overlap each other, the four square regions being a first square region having a line connecting the first vertex and the center of the semiconductor device as a diagonal line, a second square region having a line connecting the second vertex and the center of the semiconductor device as a diagonal line, a third square region having a line connecting the third vertex and the center of the semiconductor device as a diagonal line, and a fourth square region having a line connecting the fourth vertex and the center of the semiconductor device as a diagonal line: the first pad may be contained within the first square region; the second pad may be contained within a second-pad-containing square region that is one of the second square region or the fourth square region; the third pad may be contained within the third square region; and the fourth pad may be contained within a fourth-pad-containing square region that is an other of the second square region or the fourth square region. The semiconductor layer may further include a drain lead-out region of the first conductivity type, the drain lead-out region being entirely contained within the second-pad-containing square region in a plan view of the semiconductor layer, penetrating through the low-concentration impurity layer from an upper surface of the semiconductor layer to the semiconductor substrate, and containing an impurity having a third concentration higher than the second concentration. In the plan view of the semiconductor device, the semiconductor device may further include: a first electrode that is at least partially contained within the first square region and functions as a source electrode of the vertical MOS transistor; a second electrode that is at least partially contained within the second-pad-containing square region, functions as a drain electrode of the vertical MOS transistor, functions as a cathode electrode of the Schottky barrier diode when the first conductivity type is the N type, and functions as an anode electrode of the Schottky barrier diode when the first conductivity type is the P type; a third electrode that is at least partially contained within the third square region, functions as the anode electrode of the Schottky barrier diode when the first conductivity type is the N type, and functions as the cathode electrode of the Schottky barrier diode when the first conductivity type is the P type; and a fourth electrode that is at least partially contained within the fourth-pad-containing square region and functions as a gate electrode of the vertical MOS transistor.

In the semiconductor device thus configured, a distance between the anode electrode and the cathode electrode of the Schottky barrier diode is relatively shortened.

Accordingly, the semiconductor device thus configured makes it possible to relatively reduce the forward voltage of the Schottky barrier diode.

Furthermore, in the semiconductor device thus configured, a distance between the source electrode and the drain electrode of the vertical MOS transistor is relatively shortened.

Accordingly, the semiconductor device thus configured makes it possible to relatively reduce the conduction resistance of the vertical MOS transistor.

Moreover, the Schottky barrier diode may be of a planar type.

It is generally possible to provide the Schottky barrier diode of the planar type through fewer processes than Schottky barrier diodes of other types.

Accordingly, it is possible to manufacture the semiconductor device thus configured relatively easily.

Furthermore, the second electrode may include a plurality of metal layers including an ohmic contact metal layer that is in ohmic contact with the drain lead-out region, the third electrode may include a plurality of metal layers including a Schottky contact metal layer that is in Schottky contact with the low-concentration impurity layer, and a metal material of the ohmic contact metal layer may be identical to a metal material of the Schottky contact metal layer.

For this reason, it is possible to provide the ohmic contact metal layer and the Schottky contact metal layer through the same process.

Accordingly, it is possible to manufacture the semiconductor device thus configured relatively easily.

Moreover, the second electrode may include a plurality of metal layers including an ohmic contact metal layer that is in ohmic contact with the drain lead-out region, the third electrode may include a plurality of metal layers including a Schottky contact metal layer that is in Schottky contact with the low-concentration impurity layer, and a metal material of the ohmic contact metal layer may be different from a metal material of the Schottky contact metal layer.

For this reason, it is possible to allow the Schottky contact metal layer to be a metal layer that is designed for desired characteristics of the Schottky barrier diode and includes a metal material of a different type from the ohmic contact metal layer.

Accordingly, the semiconductor device thus configured including the Schottky barrier diode having the desired characteristics is provided.

Furthermore, in the plan view of the semiconductor device: the first electrode may be at least partially contained within at least one of the second-pad-containing square region or the fourth-pad-containing square region, and at least a portion of the second electrode, at least a portion of the third electrode, and at least a portion of the fourth electrode need not be contained within the first square region.

For this reason, it is possible to relatively increase the area of the source electrode of the vertical MOS transistor in the plan view of the semiconductor device.

Accordingly, the semiconductor device thus configured makes it possible to relatively reduce the conduction resistance of the vertical MOS transistor.

Moreover, in the plan view of the semiconductor device, the second electrode may be a rectangle including a first opposite side and a second opposite side, the first opposite side including a portion parallel and opposite to a first portion of a peripheral side of the first electrode, the second opposite side including a portion parallel and opposite to a second portion of the peripheral side of the first electrode.

For this reason, it is possible to relatively increase the length of a boundary at which the source electrode and the drain electrode of the vertical MOS transistor are opposite to each other in the plan view of the semiconductor device.

Accordingly, the semiconductor device thus configured makes it possible to relatively reduce the conduction resistance of the vertical MOS transistor.

Furthermore, in the plan view of the semiconductor device, at least a portion of the first electrode need not be contained within the second-pad-containing square region.

In the semiconductor device thus configured, the source electrode of the vertical MOS transistor is not interposed between the anode electrode and the cathode electrode of the Schottky barrier diode in the plan view of the semiconductor device.

Accordingly, the semiconductor device thus configured makes it possible to reduce the degradation of the characteristics of the Schottky barrier diode.

Moreover, the third electrode and the low-concentration impurity layer may be in Schottky contact in a Schottky contact region, the second electrode and the drain lead-out region may be in ohmic contact in an ohmic contact region, the first electrode and the semiconductor layer may be in contact with each other in a source contact region, and in the plan view of the semiconductor device: the Schottky contact region may be contained within the third electrode and is one of a circle, an ellipse, an oblong, or a rounded-corner rectangle obtained by rounding off each of corners of a rectangle; and a shortest distance between the Schottky contact region and the ohmic contact region may be less than a shortest distance between the Schottky contact region and the source contact region.

The semiconductor device thus configured does not include a corner portion in the Schottky contact region in the plan view of the semiconductor device.

For this reason, an excessive electric field concentration in the Schottky contact region is mitigated.

Accordingly, the semiconductor device thus configured makes it possible to improve breakdown voltage characteristics in the Schottky contact region.

In addition, the semiconductor device thus configured makes it possible to relatively shorten a distance between the Schottky contact region and the ohmic contact region.

Accordingly, the semiconductor device thus configured makes it possible to relatively reduce the forward voltage of the Schottky barrier diode.

Furthermore, in the plan view of the semiconductor device, an area of the Schottky contact region may be larger than an area of the third pad.

For this reason, it is possible to relatively increase the area of the Schottky contact region in the plan view of the semiconductor device.

Accordingly, the semiconductor device thus configured makes it possible to relatively reduce the forward voltage of the Schottky barrier diode.

Moreover, in the plan view of the semiconductor device, an area of the Schottky contact region may be smaller than an area of the third pad.

For this reason, it is possible to relatively decrease the area of the Schottky contact region in the plan view of the semiconductor device.

Accordingly, the semiconductor device thus configured makes it possible to relatively reduce the reverse leakage current of the Schottky barrier diode.

Furthermore, the third electrode and the low-concentration impurity layer may be in Schottky contact in a Schottky contact region, the first electrode and the semiconductor layer may be in contact with each other in a source contact region, and in the plan view of the semiconductor device: the Schottky contact region may be one of a circle, an ellipse, an oblong, or a rounded-corner rectangle obtained by rounding off each of corners of a rectangle; the source contact region may be a rounded-corner rectangle obtained by rounding off each of corners of a polygon; and a minimum curvature radius in a periphery of the Schottky contact region may be greater than or equal to a minimum curvature radius in the source contact region.

For this reason, it is possible to allow the mitigation of an excessive electric field concentration in the Schottky contact region to be greater than or equal to the mitigation of an excessive electric field concentration in the source contact region.

Accordingly, the semiconductor device thus configured makes it possible to allow breakdown voltage characteristics as the semiconductor device to be defined not by the excessive electric field concentration in the Schottky contact region but by the excessive electric field concentration in the source contact region.

Hereinafter, specific examples of a semiconductor device according to one aspect of the present disclosure are described with reference to the Drawings. An embodiment described below shows a specific example of the present disclosure. Accordingly, the numerical values, shapes, constituent elements, the arrangement and connection of the constituent elements, steps (processes), and the order of steps, etc. shown in the following embodiment are mere examples, and are not intended to limit the present disclosure. In addition, each of figures is a schematic diagram and is not necessarily a precise illustration. In each figure, substantially identical constituent elements are assigned the same reference signs, and overlapping descriptions are omitted or simplified.

### Embodiment

Hereinafter, a semiconductor device according to an embodiment is described. The semiconductor device is a chip-size-package type semiconductor device that includes a vertical metal-oxide-semiconductor (MOS) transistor and a Schottky barrier diode.

### <Structure of Semiconductor Device>

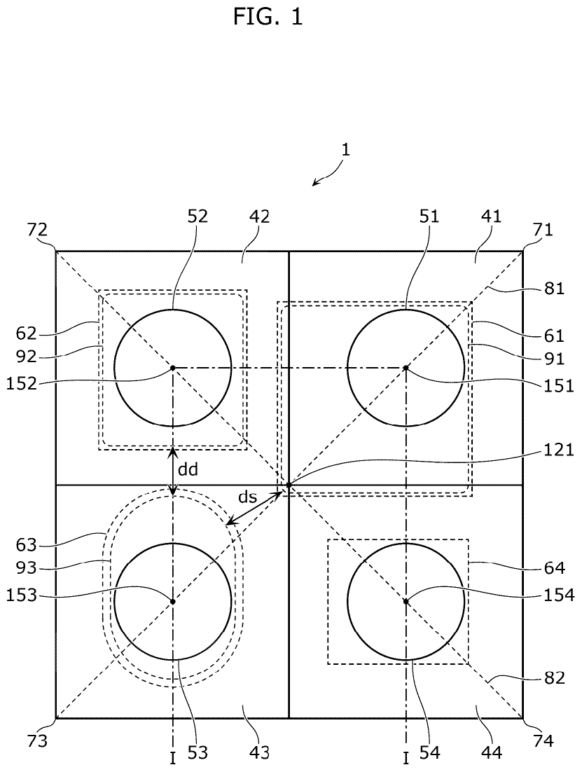

FIG. 1 is a planar schematic diagram showing an example of a structure of semiconductor device 1 according to the embodiment. In FIG. 1, first electrode 61 (to be described later), second electrode 62 (to be described later), third electrode 63 (to be described later), fourth electrode 64 (to be described later), source contact region 91 (to be described later), ohmic contact region 92 (to be described later), and Schottky contact region 93 (to be described later) are shown by dashed lines as if these electrodes and regions could be visually recognized from the outside of semiconductor device 1; but actually these electrodes and regions cannot be visually recognized directly from the outside of semiconductor device 1.

As shown in FIG. 1, in a plan view of semiconductor device 1, semiconductor device 1 is a square including first vertex 71, second vertex 72, third vertex 73, and fourth vertex 74 in a counterclockwise direction.

Here, in the Description, that semiconductor device 1 is a square refers, among rectangles, not only to a shape whose ratio of longer side to shorter side is exactly 1.0 but also to a shape whose ratio of longer side to shorter side is within a range of 0.9 to 1.1.

Semiconductor device 1 includes first pad 51, second pad 52, third pad 53, and fourth pad 54 on the upper surface of semiconductor device 1.

In the plan view of semiconductor device 1, first pad 51, second pad 52, third pad 53, and fourth pad 54 are circles each having an equal diameter.

Here, in the Description, that a pad is a circle refers not only to an exact circle but also to a substantially circle obtained by flattening an exact circle within a range of ±1%.

In the plan view of semiconductor device 1, center 151 of first pad 51 and center 153 of third pad 53 are located on first diagonal line 81 connecting first vertex 71 and third vertex 73, and center 152 of second pad 52 and center 154 of fourth pad 54 are located on second diagonal line 82 connecting second vertex 72 and fourth vertex 74.

In the plan view of semiconductor device 1, a distance between center 121 of semiconductor device 1 and center 151 of first pad 51, a distance between center 121 of semiconductor device 1 and center 152 of second pad 52, a distance between center 121 of semiconductor device 1 and center 153 of third pad 53, and a distance between center 121 of semiconductor device 1 and center 154 of fourth pad 54 are equal.

In the following section, as shown in FIG. 1, in the plan view of semiconductor device 1, the area of semiconductor device 1 is equally divided by four square regions that are similarly shaped and do not overlap each other, the four square regions being first square region 41 having a line connecting first vertex 71 and center 121 of semiconductor device 1 as a diagonal line, second square region 42 having a line connecting second vertex 72 and center 121 of semiconductor device 1 as a diagonal line, third square region 43 having a line connecting third vertex 73 and center 121 of semiconductor device 1 as a diagonal line, and fourth square region 44 having a line connecting fourth vertex 74 and center 121 of semiconductor device 1 as a diagonal line.

In the plan view of semiconductor device 1, first pad 51 is contained within first square region 41, second pad 52 is contained within one of second square region 42 or fourth square region 44, third pad 53 is contained within third square region 43, and fourth pad 54 is contained within the other of second square region 42 or fourth square region 44.

In the present embodiment, as a non-limiting example, as shown in FIG. 1, second pad 52 is contained within second square region 42 and fourth pad 54 are contained within fourth square region 44.

In the following description, a square region (here second square region 42) that is one of second square region 42 or fourth square region 44, that is, of second square region 42 and fourth square region 44, a square region (here second square region 42) that contains second pad 52 in the plan view of semiconductor device 1 is also referred to as second-pad-containing square region 42.

Additionally, in the following description, a square region (here fourth square region 44) that is the other of second square region 42 or fourth square region 44, that is, of second square region 42 and fourth square region 44, a square region (here fourth square region 44) that contains fourth pad 54 in the plan view of semiconductor device 1 is also referred to as fourth-pad-containing square region 44.

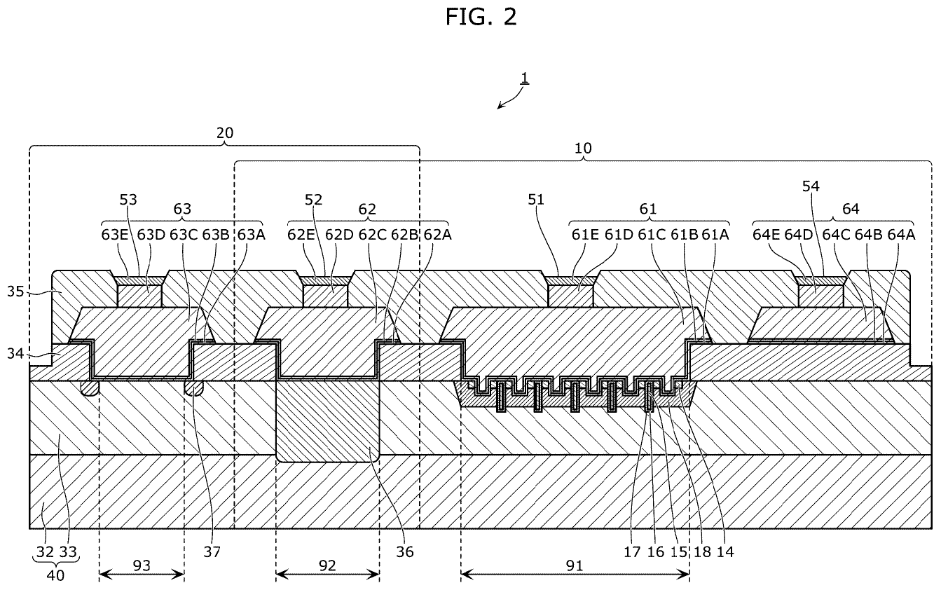

FIG. 2 is a cross-sectional schematic diagram showing an example of a configuration of semiconductor device 1, and is a cross-sectional schematic diagram schematically showing a cross section of semiconductor device 1 taken along line I-I in FIG. 1.

Hereinafter, the description of the structure of semiconductor device 1 continues with reference to FIG. 2 in addition to FIG. 1.

As shown in FIG. 2, semiconductor device 1 includes semiconductor layer 40, interlayer insulating layer 34, passivation layer 35, first electrode 61, second electrode 62, third electrode 63, and fourth electrode 64.

Semiconductor layer 40 is configured by stacking semiconductor substrate 32 and low-concentration impurity layer 33.

Semiconductor substrate 32 is disposed on a back surface side of semiconductor layer 40 and comprises silicon of a first conductivity type that contains impurities having a first concentration.

Low-concentration impurity layer 33 is disposed on a front surface side of semiconductor layer 40, is provided in contact with semiconductor substrate 32, and comprises silicon of the first conductivity type that contains impurities having a second concentration lower than the first concentration. Low-concentration impurity layer 33 may be provided on semiconductor substrate 32 by, for example, epitaxial growth.

Here, the second concentration is a concentration at which a Schottky barrier is provided on a contact surface between low-concentration impurity layer 33 and first metal layer 63A to be described later when low-concentration impurity layer 33 comes into contact with first metal layer 63A. In other words, the second concentration is a concentration at which low-concentration impurity layer 33 and first metal layer 63A are brought into Schottky contact on the contact surface between low-concentration impurity layer 33 and first metal layer 63A.

In general, semiconductor conductivity types include two kinds of conductivity types that are P type and N type. The first conductivity type may be the P type or the N type. For convenience, in the following description, the first conductivity type is the N type and a second conductivity type to be described later is the P type. However, the first conductivity type may be the P type and the second conductivity type may be the N type.

Interlayer insulating layer 34 is disposed on an upper surface of semiconductor layer 40, is disposed on an upper surface of gate conductor 15 inside gate trench 17 to be described later, and is provided in contact with low-concentration impurity layer 33. It should be noted that interlayer insulating layer 34 is provided using mainly an oxide film.

Passivation layer 35 is a protective film that covers upper surfaces of interlayer insulating layer 34, first electrode 61, second electrode 62, third electrode 63, and fourth electrode 64, and includes an opening that exposes first pad 51 to the outside of semiconductor device 1, an opening that exposes second pad 52 to the outside of semiconductor device 1, an opening that exposes third pad 53 to the outside of semiconductor device 1, and an opening that exposes fourth pad 54 to the outside of semiconductor device 1.

Here, that passivation layer 35 covers the upper surfaces of interlayer insulating layer 34, first electrode 61, second electrode 62, third electrode 63, and fourth electrode 64 refers to a state in which passivation layer 35 is deposited on substantially the entire surface of semiconductor device 1 except the openings in the plan view of semiconductor device 1. Here, substantially the entire surface of semiconductor device 1 refers to the entire surface of semiconductor device 1 excluding a peripheral region of a wafer region, the wafer region being reserved as a dicing margin when semiconductor device 1 is diced from a wafer, the peripheral region slightly remaining in the four sides of semiconductor device 1 after the dicing. For this reason, in the peripheral region, interlayer insulating layer 34 is exceptionally exposed on the upper surface of semiconductor layer 1.

In addition, an opening of passivation layer 35 described in the present disclosure refers to a shape defined by a closed periphery of an opening in passivation layer 35 in the plan view of semiconductor device 1. For this reason, a shape defined by a portion of the closed periphery overlapping the peripheral region in which interlayer insulating layer 34 is exceptionally exposed on the upper surface of semiconductor device 1 in the plan view of semiconductor device 1 does not correspond to the opening of passivation layer 35 described in the present disclosure.

First electrode 61 includes: first metal layer 61A provided on the upper surface of semiconductor layer 40; second metal layer 61B provided on an upper surface of first metal layer 61A; third metal layer 61C provided on an upper surface of second metal layer 61B; fourth metal layer 61D provided on an upper surface of third metal layer 61C; and fifth metal layer 61E provided on an upper surface of fourth metal layer 61D.

First metal layer 61A comprises, as a non-limiting example, titanium having a thickness of several tens of nm, and functions as a metal component included in a contact surface on which first electrode 61 and semiconductor layer 40 are in contact with each other.

First metal layer 61A may be provided by, for example, sputtering titanium onto the upper surface of semiconductor layer 40.

Second metal layer 61B comprises, as a non-limiting example, titanium nitride having a thickness of several tens of nm, and functions as a barrier metal that stops the diffusion of metal comprised in third metal layer 61C into semiconductor layer 40.

Second metal layer 61B may be provided by, for example, sputtering titanium nitride onto the upper surface of first metal layer 61A.

Third metal layer 61C comprises, as a non-limiting example, aluminum having a thickness of several μm or alloy including aluminum as a main component.

Third metal layer 61C may be provided by, for example, sputtering aluminum or the alloy including aluminum as the main component onto the upper surface of second metal layer 61B.

Fourth metal layer 61D comprises, as a non-limiting example, nickel having a thickness of several μm, and functions as a barrier metal that stops the diffusion of metal comprised in third metal layer 61C into fifth metal layer 61E to be described later.

Fourth metal layer 61D may be provided by, for example, plating nickel on the upper surface of third metal layer 61C.

Fifth metal layer 61E comprises, as a non-limiting example, gold having a thickness of several hundreds of nm, and functions as a metal component for increasing wettability when first electrode 61 is bonded to a bonding material such as solder.

Fifth metal layer 61E may be provided by, for example, plating gold on the upper surface of fourth metal layer 61D.

An upper surface of fifth metal layer 61E is exposed on the upper surface of semiconductor device 1 through the opening of passivation layer 35. The upper surface of fifth metal layer 61E exposed on the upper surface of semiconductor device 1 through the opening of passivation layer 35 is first pad 51.

In other words, first pad 51 is a portion of the upper surface of first electrode 61 exposed on the upper surface of semiconductor device 1 through the opening of passivation layer 35.

As shown in FIG. 1, in the plan view of semiconductor device 1, first electrode 61 is at least partially contained within first square region 41.

In the following description, as a non-limiting example, as shown in FIG. 1, in the plan view of semiconductor device 1, first electrode 61 is at least partially contained within second square region 42, third square region 43, and fourth square region 44.

However, in the plan view of semiconductor device 1, first electrode 61 need not be at least partially contained within second square region 42, third square region 43, and fourth square region 44.

Second electrode 62 includes: first metal layer 62A provided on the upper surface of semiconductor layer 40; second metal layer 62B provided on an upper surface of first metal layer 62A; third metal layer 62C provided on an upper surface of second metal layer 62B; fourth metal layer 62D provided on an upper surface of third metal layer 62C; and fifth metal layer 62E provided on an upper surface of fourth metal layer 62D.

First metal layer 62A comprises, as a non-limiting example, titanium having a thickness of several tens of nm, and functions as a metal component included in a contact surface on which second electrode 62 and semiconductor layer 40 are in contact with each other.

First metal layer 62A may be provided by, for example, sputtering titanium onto the upper surface of semiconductor layer 40.

Second metal layer 62B comprises, as a non-limiting example, titanium nitride having a thickness of several tens of nm, and functions as a barrier metal that stops the diffusion of metal comprised in third metal layer 62C into semiconductor layer 40.

Second metal layer 62B may be provided by, for example, sputtering titanium nitride onto the upper surface of first metal layer 62A.

Third metal layer 62C comprises, as a non-limiting example, aluminum having a thickness of several μm or alloy including aluminum as a main component.

Third metal layer 62C may be provided by, for example, sputtering aluminum or the alloy including aluminum as the main component onto the upper surface of second metal layer 62B.

Fourth metal layer 62D comprises, as a non-limiting example, nickel having a thickness of several μm, and functions as a barrier metal that stops the diffusion of metal comprised in third metal layer 62C into fifth metal layer 62E to be described later.

Fourth metal layer 62D may be provided by, for example, plating nickel on the upper surface of third metal layer 62C.

Fifth metal layer 62E comprises, as a non-limiting example, gold having a thickness of several hundreds of nm, and functions as a metal component for increasing wettability when second electrode 62 is bonded to a bonding material such as solder.

Fifth metal layer 62E may be provided by, for example, plating gold on the upper surface of fourth metal layer 62D.

An upper surface of fifth metal layer 62E is exposed on the upper surface of semiconductor device 1 through the opening of passivation layer 35. The upper surface of fifth metal layer 62E exposed on the upper surface of semiconductor device 1 through the opening of passivation layer 35 is second pad 52.

In other words, second pad 52 is a portion of the upper surface of second electrode 62 exposed on the upper surface of semiconductor device 1 through the opening of passivation layer 35.

As shown in FIG. 1, in the plan view of semiconductor device 1, second electrode 62 is at least partially contained within second square region 42, that is, second-pad-containing square region 42.

In the following description, as a non-limiting example, as shown in FIG. 1, in the plan view of semiconductor device 1, second electrode 62 is entirely contained within second square region 42, that is, second-pad-containing square region 42.

Third electrode 63 includes: first metal layer 63A provided on the upper surface of semiconductor layer 40; second metal layer 63B provided on an upper surface of first metal layer 63A; third metal layer 63C provided on an upper surface of second metal layer 63B; fourth metal layer 63D provided on an upper surface of third metal layer 63C; and fifth metal layer 63E provided on an upper surface of fourth metal layer 63D.

First metal layer 63A comprises, as a non-limiting example, titanium, vanadium, molybdenum, tungsten, or platinum having a thickness of several tens of nm, and functions as a metal component included in a contact surface on which third electrode 63 and semiconductor layer 40 are in contact with each other.

First metal layer 63A may be provided by, for example, sputtering titanium, vanadium, molybdenum, tungsten, or platinum onto the upper surface of semiconductor layer 40.

Second metal layer 63B comprises, as a non-limiting example, titanium nitride having a thickness of several tens of nm, and functions as a barrier metal that stops the diffusion of metal comprised in third metal layer 63C into semiconductor layer 40.

Second metal layer 63B may be provided by, for example, sputtering titanium nitride onto the upper surface of first metal layer 63A.

Third metal layer 63C comprises, as a non-limiting example, aluminum having a thickness of several μm or alloy including aluminum as a main component.

Third metal layer 63C may be provided by, for example, sputtering aluminum or the alloy including aluminum as the main component onto the upper surface of second metal layer 63B.

Fourth metal layer 63D comprises, as a non-limiting example, nickel having a thickness of several μm, and functions as a barrier metal that stops the diffusion of metal comprised in third metal layer 63C into fifth metal layer 63E to be described later.

Fourth metal layer 63D may be provided by, for example, plating nickel on the upper surface of third metal layer 63C.

Fifth metal layer 63E comprises, as a non-limiting example, gold having a thickness of several hundreds of nm, and functions as a metal component for increasing wettability when third electrode 63 is bonded to a bonding material such as solder.

Fifth metal layer 63E may be provided by, for example, plating gold on the upper surface of fourth metal layer 63D.

An upper surface of fifth metal layer 63E is exposed on the upper surface of semiconductor device 1 through the opening of passivation layer 35. The upper surface of fifth metal layer 63E exposed on the upper surface of semiconductor device 1 through the opening of passivation layer 35 is third pad 53.

In other words, third pad 53 is a portion of the upper surface of third electrode 63 exposed on the upper surface of semiconductor device 1 through the opening of passivation layer 35.

As shown in FIG. 1, in the plan view of semiconductor device 1, third electrode 63 is at least partially contained within third square region 43.

In the following description, as a non-limiting example, as shown in FIG. 1, in the plan view of semiconductor device 1, third electrode 63 is entirely contained within third square region 43.

Fourth electrode 64 includes: first metal layer 64A provided on an upper surface of interlayer insulating layer 34; second metal layer 64B provided on an upper surface of first metal layer 64A; third metal layer 64C provided on an upper surface of second metal layer 64B; fourth metal layer 64D provided on an upper surface of third metal layer 64C; and fifth metal layer 64E provided on an upper surface of fourth metal layer 64D.

First metal layer 64A comprises, as a non-limiting example, titanium having a thickness of several tens of nm.

First metal layer 64A may be provided by, for example, sputtering titanium onto the upper surface of interlayer insulating layer 34.

Second metal layer 64B comprises, as a non-limiting example, titanium nitride having a thickness of several tens of nm.

Second metal layer 64B may be provided by, for example, sputtering titanium nitride onto the upper surface of first metal layer 64A.

Third metal layer 64C comprises, as a non-limiting example, aluminum having a thickness of several μm or alloy including aluminum as a main component.

Third metal layer 64C may be provided by, for example, sputtering aluminum or the alloy including aluminum as the main component onto the upper surface of second metal layer 64B.

Fourth metal layer 64D comprises, as a non-limiting example, nickel having a thickness of several μm, and functions as a barrier metal that stops the diffusion of metal comprised in third metal layer 64C into fifth metal layer 64E to be described later.

Fourth metal layer 64D may be provided by, for example, plating nickel on the upper surface of third metal layer 64C.

Fifth metal layer 64E comprises, as a non-limiting example, gold having a thickness of several hundreds of nm, and functions as a metal component for increasing wettability when fourth electrode 64 is bonded to a bonding material such as solder.

Fifth metal layer 64E may be provided by, for example, plating gold on the upper surface of fourth metal layer 64D.

An upper surface of fifth metal layer 64E is exposed on the upper surface of semiconductor device 1 through the opening of passivation layer 35. The upper surface of fifth metal layer 64E exposed on the upper surface of semiconductor device 1 through the opening of passivation layer 35 is fourth pad 54.

In other words, fourth pad 54 is a portion of the upper surface of fourth electrode 64 exposed on the upper surface of semiconductor device 1 through the opening of passivation layer 35.

As shown in FIG. 1, in the plan view of semiconductor device 1, fourth electrode 64 is at least partially contained within fourth square region 44, that is, fourth-pad-containing square region 44.

In the following description, as a non-limiting example, as shown in FIG. 1, in the plan view of semiconductor device 1, fourth electrode 64 is entirely contained within fourth square region 44, that is, fourth-pad-containing square region 44.

In the plan view of semiconductor device 1, body region 18 containing impurities of the second conductivity type different from the first conductivity type is provided in a region of low-concentration impurity layer 33 contained within first electrode 61, in a range from the upper surface of semiconductor layer 40 to a first predetermined depth.

Source region 14 of the first conductivity type containing impurities is provided in body region 18 in a range from the upper surface of semiconductor layer 40 to a second predetermined depth at which body region 18 is not penetrated.

In addition, in the plan view of semiconductor device 1, a plurality of gate trenches 17 are provided in a region of low-concentration impurity layer 33 contained within body region 18, in a range from the upper surface of semiconductor layer 40 to a third predetermined depth at which source region 14 and body region 18 are penetrated to a portion of low-concentration impurity layer 33.

Gate conductor 15 surrounded by gate insulating film 16 is provided inside each of the plurality of gate trenches 17.

Each of gate conductors 15 is electrically connected to fourth electrode 64.

Gate conductor 15 comprises, as a non-limiting example, polysilicon containing impurities.

In the plan view of semiconductor device 1, the upper surface of semiconductor layer 40 is in contact with first metal layer 61A in the region contained within first electrode 61.

In the following description, a region in which the upper surface of semiconductor layer 40 and first metal layer 61A are in contact with each other is referred to as source contact region 91.

In the plan view of semiconductor device 1, drain lead-out region 36 of the first conductivity type is provided in a region of low-concentration impurity layer 33 contained within second electrode 62, drain lead-out region 36 penetrating from the upper surface of semiconductor layer 40 through low-concentration impurity layer 33 to semiconductor substrate 32 and containing impurities having a third concentration higher than the second concentration.

Here, the third concentration is a concentration at which a Schottky barrier is not provided on a contact surface between drain lead-out region 36 and first metal layer 62A when drain lead-out region 36 comes into contact with first metal layer 62A. In other words, the third concentration is a concentration that causes drain lead-out region 36 and first metal layer 62A to be in ohmic contact on the contact surface between drain lead-out region 36 and first metal layer 62A.

An upper surface of drain lead-out region 36 is in contact with first metal layer 62A. Accordingly, in the plan view of semiconductor device 1, the upper surface of drain lead-out region 36 and first metal layer 62A are in ohmic contact in the region contained within second electrode 62.

In the following description, a region in which the upper surface of drain lead-out region 36 and first metal layer 62A are in ohmic contact, that is, a region in which the upper surface of drain lead-out region 36 and first metal layer 62A are in contact with each other is referred to as ohmic contact region 92.

Additionally, in the following description, among the metal layers included in second electrode 62, first metal layer 62A in contact with the upper surface of drain lead-out region 36 in ohmic contact region 92 is also referred to as ohmic contact metal layer 62A.

In the plan view of semiconductor device 1, the upper surface of drain lead-out region 36 contains ohmic contact region 92. Accordingly, semiconductor layer 40 and first metal layer 62A, that is, ohmic contact metal layer 62A are in contact with each other only in ohmic contact region 92.

In the plan view of semiconductor device 1, an upper surface of low-concentration impurity layer 33 is in contact with first metal layer 63A in a region contained within third electrode 63. Accordingly, the upper surface of low-concentration impurity layer 33 and first metal layer 63A are in Schottky contact in the region contained within third electrode 63 in the plan view of semiconductor device 1.

In the following description, a region in which the upper surface of low-concentration impurity layer 33 and first metal layer 63A are in Schottky contact, that is, a region in which the upper surface of low-concentration impurity layer 33 and first metal layer 63A are in contact with each other is referred to as Schottky contact region 93.

Additionally, in the following description, among the metal layers included in third electrode 63, first metal layer 63A in contact with the upper surface of low-concentration impurity layer 33 in Schottky contact region 93 is also referred to as Schottky contact metal layer 63A.

Guard ring 37 containing impurities of the second conductivity type different from the first conductivity type is provided in a region of low-concentration impurity layer 33 surrounding the periphery of Schottky contact region 93 in the plan view of semiconductor device 1, in a range from the upper surface of semiconductor layer 40 to a fourth predetermined depth.

With the above configuration, semiconductor device 1 includes: vertical metal-oxide-semiconductor (MOS) transistor 10 provided in semiconductor layer 40; and Schottky barrier diode 20 in which low-concentration impurity layer 33 functions as a cathode when the first conductivity type is the N type, and low-concentration impurity layer 33 functions as an anode when the first conductivity type is the P type.

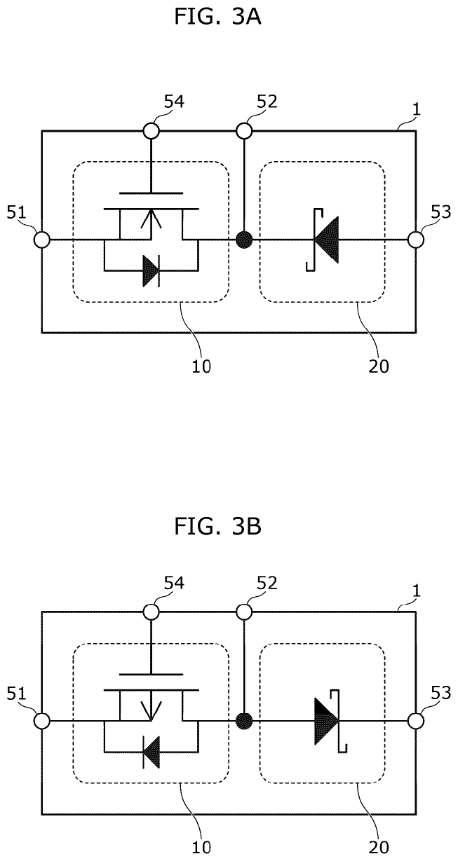

FIG. 3A is a circuit diagram of semiconductor device 1 when the first conductivity type is the N type, that is, when the second conductivity type is the P type. FIG. 3B is a circuit diagram of semiconductor device 1 when the first conductivity type is the P type, that is, when the second conductivity type is the N type.

As shown in FIG. 3A, when the first conductivity type is the N type, vertical MOS transistor 10 is vertical N-channel MOS transistor 10; first pad 51 is a pad that functions as a source pad of vertical N-channel MOS transistor 10; second pad 52 is a pad that functions as a drain pad of vertical N-channel MOS transistor 10 and as a cathode pad of Schottky barrier diode 20; third pad 53 is a pad that functions as an anode pad of Schottky barrier diode 20; and fourth pad 54 is a pad that functions as a gate pad of vertical N-channel MOS transistor 10.

In other words, when the first conductivity type is the N type, first electrode 61 is an electrode that functions as a source electrode of vertical N-channel MOS transistor 10; second electrode 62 is an electrode that functions as a drain electrode of vertical N-channel MOS transistor 10 and as a cathode electrode of Schottky barrier diode 20; third electrode 63 is an electrode that functions as an anode electrode of Schottky barrier diode 20; and fourth electrode 64 is an electrode that functions as a gate electrode of vertical N-channel MOS transistor 10.

As shown in FIG. 3B, when the first conductivity type is the P type, vertical MOS transistor 10 is vertical P-channel MOS transistor 10; first pad 51 is a pad that functions as a source pad of vertical P-channel MOS transistor 10; second pad 52 is a pad that functions as a drain pad of vertical P-channel MOS transistor 10 and as an anode pad of Schottky barrier diode 20; third pad 53 is a pad that functions as a cathode pad of Schottky barrier diode 20; and fourth pad 54 is a pad that functions as a gate pad of vertical P-channel MOS transistor 10.

To put it another way, when the first conductivity type is the P type, first electrode 61 is an electrode that functions as a source electrode of vertical P-channel MOS transistor 10; second electrode 62 is an electrode that functions as a drain electrode of vertical P-channel MOS transistor 10 and as an anode electrode of Schottky barrier diode 20; third electrode 63 is an electrode that functions as a cathode electrode of Schottky barrier diode 20; and fourth electrode 64 is an electrode that functions as a gate electrode of vertical P-channel MOS transistor 10.

### <Discussion>

Semiconductor device 1 thus configured is an unmolded chip-size-package type semiconductor device in which a vertical MOS transistor and a Schottky barrier diode each function as an independent element and that includes four pads, that is, four terminals on an upper surface that is a mounting surface at which the unmolded chip-size-package type semiconductor device is mounted on, for example, a mounting substrate.

Accordingly, semiconductor device 1 thus configured makes it possible to reduce its size in a plan view, compared to a conventional semiconductor device in which a MOS transistor and a Schottky barrier diode are molded in one package to allow each of the MOS transistor and the Schottky barrier diode to function as an independent element and that includes at least five terminals on a mounting surface.

As stated above, semiconductor device 1 thus configured includes a MOS transistor and a Schottky barrier diode each of which functions as an independent element, and makes it possible to reduce its size in a plan view more than ever before.

Semiconductor devices that are conventionally commercially available, in each of which a MOS transistor and a Schottky barrier diode are molded in one package to allow each of the MOS transistor and the Schottky barrier diode to function as an independent element, and each of which includes at least five terminals on a mounting surface, have a size of at least 2.0 mm×2.0 mm in a plan view of the semiconductor devices. In contrast, semiconductor device 1 typically has a size of 0.6 mm×0.6 mm in the plan view of semiconductor device 1.

In semiconductor device 1 thus configured, in the plan view of semiconductor device 1, at least a portion of first electrode 61 is contained within first square region 41; second electrode 62 is contained within a square region that is one of second square region 42 or fourth square region 44; third electrode 63 is contained within third square region 43; and fourth electrode 64 is contained within a square region that is the other of second square region 42 or fourth square region 44.

For this reason, it is possible to relatively shorten a distance between the anode electrode and the cathode electrode of Schottky barrier diode 20, and relatively shorten a distance between the source electrode and the drain electrode of vertical MOS transistor 10.

Accordingly, semiconductor device 1 thus configured makes it possible to relatively reduce the forward voltage of Schottky barrier diode 20, and relatively reduce the conduction resistance of vertical MOS transistor 10.

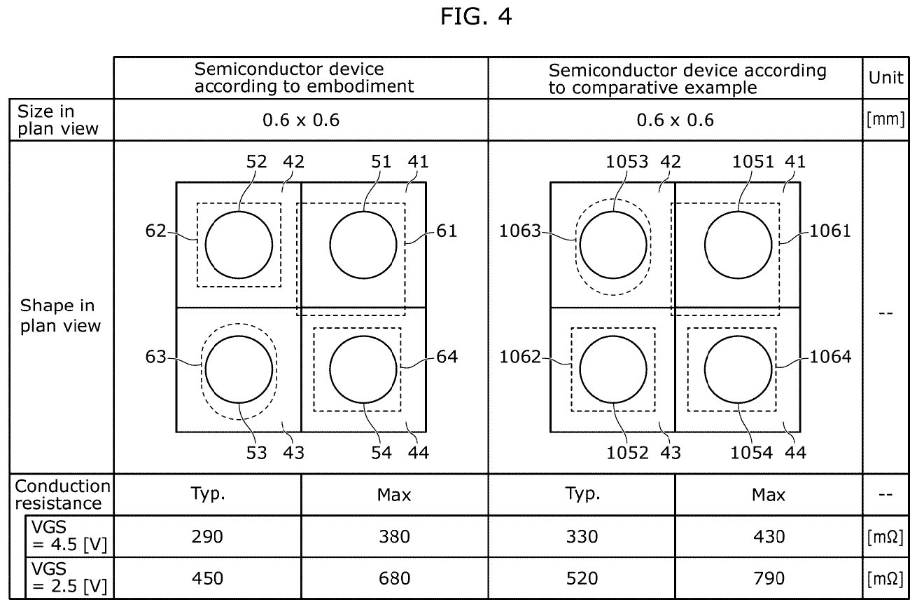

FIG. 4 is a comparative chart that compares the conduction resistance of a vertical MOS transistor according to a comparative example in semiconductor device 1000 according to the comparative example and the conduction resistance of vertical MOS transistor 10 in semiconductor device 1, semiconductor device 1000 being configured by switching the position of second electrode 62 and the position of third electrode 63 in semiconductor device 1 in the plan view of semiconductor device 1.

In other words, as shown in FIG. 4, semiconductor device 1000 according to the comparative example is configured by containing at least a portion of first electrode 1061 and first pad 1051 within first square region 41, containing third electrode 1063 and third pad 1053 within second square region 42, containing second electrode 1062 and second pad 1052 within third square region 43, and containing fourth electrode 1064 and fourth pad 1054 within fourth square region 44 in a plan view of semiconductor device 1000.

In FIG. 4, VGS represents the gate-to-source applied voltages of a vertical MOS transistor according to the comparative example and vertical MOS transistor 10.

Additionally, in FIG. 4, values of the conduction resistance of the vertical MOS transistor according to the comparative example and values of the conduction resistance of vertical MOS transistor 10 are examples of simulation values obtained when simulations are conducted under the same conditions.

As shown in FIG. 4, the values of the conduction resistance of vertical MOS transistor 10 are lower than the values of the conduction resistance of the vertical MOS transistor according to the comparative example.

As stated above, by containing first electrode 61 within first square region 41, containing second electrode 62 within a square region that is one of second square region 42 or fourth square region 44, containing third electrode 63 within third square region 43, and containing fourth electrode 64 within a square region that is the other of second square region 42 or fourth square region 44 in the plan view of semiconductor device 1, semiconductor device 1 makes it possible to relatively reduce the conduction resistance of vertical MOS transistor 10.

In the present embodiment, as shown in FIG. 2, Schottky barrier diode 20 is described as a planar type. Here, a Schottky barrier diode of the planar type refers to a Schottky barrier diode having a structure in which a single impurity-doped semiconductor and metal are in Schottky contact in a flat portion of the single impurity-doped semiconductor.

However, that Schottky barrier diode 20 is of the planar type is an example, and Schottky barrier diode 20 is not necessarily limited to the planar type.

It should be noted that it is generally possible to provide the Schottky barrier diode of the planar type through relatively fewer processes. For this reason, when Schottky barrier diode 20 is of the planar type, it is possible to manufacture semiconductor device 1 relatively easily.

It should be noted that a metal component of first metal layer 61A, a metal component of first metal layer 62A, a metal component of first metal layer 63A, and a metal component of first metal layer 64A may be identical; a metal component of second metal layer 61B, a metal component of second metal layer 62B, a metal component of second metal layer 63B, and a metal component of second metal layer 64B may be identical; a metal component of third metal layer 61C, a metal component of third metal layer 62C, a metal component of third metal layer 63C, and a metal component of third metal layer 64C may be identical; a metal component of fourth metal layer 61D, a metal component of fourth metal layer 62D, a metal component of fourth metal layer 63D, and a metal component of fourth metal layer 64D may be identical; and a metal component of fifth metal layer 61E, a metal component of fifth metal layer 62E, a metal component of fifth metal layer 63E, and a metal component of fifth metal layer 64E may be identical.

Accordingly, it is possible to provide first metal layer 61A to first metal layer 64A through the same process, provide second metal layer 61B to second metal layer 64B through the same process, provide third metal layer 61C to third metal layer 64C through the same process, provide fourth metal layer 61D to fourth metal layer 64D through the same process, and provide fifth metal layer 61E to fifth metal layer 64E through the same process.

As a result, it is possible to manufacture semiconductor device 1 relatively easily.

On the other hand, a metal material of first metal layer 62A, that is, ohmic contact metal layer 62A may be different from a metal material of first metal layer 63A, that is, Schottky contact metal layer 63A.

Accordingly, it is possible to allow the characteristics of Schottky barrier diode 20 to be desired characteristics that cannot be achieved when the metal material of ohmic contact metal layer 62A is identical to the metal material of Schottky contact metal layer 63A.

In general, the characteristics of a Schottky barrier diode vary depending on the type of metal material included in a Schottky contact surface.

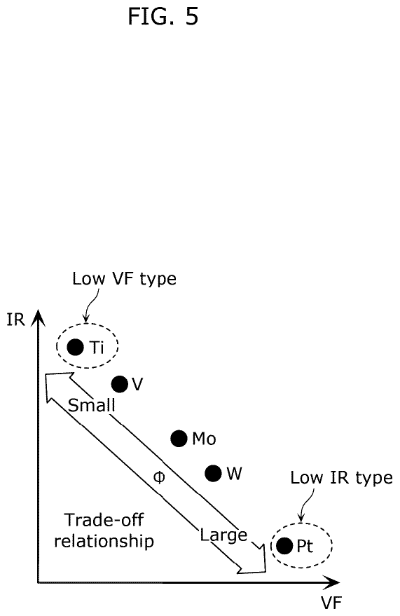

FIG. 5 is a correlation diagram schematically showing a relationship between the type of metal material included in a Schottky contact surface and the characteristics of a Schottky barrier diode when the first conductivity type is the N type.

In FIG. 5, Φ represents the size of a Schottky barrier in the Schottky barrier diode, VF represents the forward voltage of the Schottky barrier diode, and IR represents the reverse leakage current of the Schottky barrier diode. Additionally, in FIG. 5, Ti indicates that a metal material is titanium, V indicates that a metal material is vanadium, Mo indicates that a metal material is molybdenum, W indicates that a metal material is tungsten, and Pt indicates that a metal material is platinum.

As shown in FIG. 5, generally, forward voltage VF and reverse leakage current IR of the Schottky barrier diode are in a trade-off relationship.

Consequently, in the case where it is not possible to achieve the desired characteristics of Schottky barrier diode 20 when the metal materials of ohmic contact metal layer 62A and Schottky contact metal layer 63A are identical, by causing the metal material of Schottky contact metal layer 63A to be an appropriate metal material different from the metal material of ohmic contact metal layer 62A, the desired characteristics of Schottky barrier diode 20 that cannot be achieved when the metal materials of ohmic contact metal layer 62A and Schottky contact metal layer 63A are identical may be achieved.

For example, on the one hand, it is not possible to achieve the desired characteristics of Schottky barrier diode 20 when the metal components of ohmic contact metal layer 62A and Schottky contact metal layer 63A are titanium. On the other hand, in the case where it is possible to achieve the desired characteristics of Schottky barrier diode 20 when the metal component of Schottky contact metal layer 63A is platinum, the metal component of Schottky contact metal layer 63A may be caused to be platinum different from titanium that is the metal component of ohmic contact metal layer 62A.

It should be noted that, as shown in FIG. 1, in the plan view of semiconductor device 1, Schottky contact region 93 may be one of a circle, an ellipse, an oblong, or a rounded-corner rectangle obtained by rounding off each of the corners of a rectangle (the oblong in the example shown in FIG. 1).

Schottky contact region 93 thus configured includes no corner portions. As a result, an excessive electric field concentration in Schottky contact region 93 is mitigated.

Accordingly, semiconductor device 1 thus configured makes it possible to improve breakdown voltage characteristics in Schottky contact region 93.

It should be noted that, as shown in FIG. 1, in the plan view of semiconductor device 1, shortest distance dd between Schottky contact region 93 and ohmic contact region 92 may be less than shortest distance ds between Schottky contact region 93 and source contact region 91.

Semiconductor device 1 thus configured makes it possible to relatively shorten a distance between Schottky contact region 93 and ohmic contact region 92.

Accordingly, semiconductor device 1 thus configured makes it possible to relatively reduce the forward voltage of Schottky barrier diode 20.

It should be noted that a magnitude relationship between the area of Schottky contact region 93 and the area of third pad 53 in the plan view of semiconductor device 1 may be defined as the area of Schottky contact region 93 being larger than the area of third pad 53 as exemplified in FIG. 1 or, conversely, the area of Schottky contact region 93 being smaller than the area of third pad 53.

When the area of Schottky contact region 93 is larger than the area of third pad 53 in the plan view of semiconductor device 1, it is possible to relatively increase the area of Schottky contact region 93.

For this reason, it is possible to relatively reduce the forward conduction resistance of Schottky barrier diode 20.

Accordingly, semiconductor device 1 thus configured makes it possible to relatively reduce the forward voltage of Schottky barrier diode 20.

Moreover, when the area of Schottky contact region 93 is smaller than the area of third pad 53 in the plan view of semiconductor device 1, it is possible to relatively decrease the area of Schottky contact region 93.

Accordingly, semiconductor device 1 thus configured makes it possible to relatively reduce the reverse leakage current of Schottky barrier diode 20.

It should be noted that, as shown in FIG. 1, in the plan view of semiconductor device 1, Schottky contact region 93 may be one of a circle, an ellipse, an oblong, or a rounded-corner rectangle obtained by rounding off each of the corners of a rectangle, source contact region 91 may be a rounded-corner rectangle (exemplified as a rounded-corner rectangle obtained by rounding of each of the corners of a rectangle in the present embodiment, exemplified as a rounded-corner rectangle obtained by rounding off each of the corners of a polygon having more corners than a rectangle in Variation 1 and Variation 2 to be described later) obtained by rounding off each of the corners of a polygon, and a minimum radius curvature in the periphery of Schottky contact region 93 may be greater than or equal to a minimum radius curvature in source contact region 91.

In consequence, it is possible to allow the mitigation of an excessive electric field concentration in Schottky contact region 93 to be greater than or equal to the mitigation of an excessive electric field concentration in source contact region 91.

Accordingly, semiconductor device 1 thus configured makes it possible to allow breakdown voltage characteristics as semiconductor device 1 to be defined not by the excessive electric field concentration in Schottky contact region 93 but by the excessive electric field concentration in source contact region 91.

It should be noted that, as stated above, in the present embodiment, as a non-limiting example, first electrode 61 is described as being at least partially contained within second square region 42, third square region 43, and fourth square region 44 in the plan view of semiconductor device 1.

In this case, as shown in FIG. 1, in the plan view of semiconductor device 1, at least a portion of second electrode 62, at least a portion of third electrode 63, and at least a portion of fourth electrode 64 need not be contained within first square region 41.

Accordingly, semiconductor device 1 makes it possible to relatively enlarge an active region that is a region entirely containing a portion of vertical MOS transistor 10 in which a channel is formed when a voltage greater than or equal to a threshold value is applied to gate conductor 15. For this reason, semiconductor device 1 makes it possible to relatively reduce the conduction resistance of vertical MOS transistor 10.

On the other hand, as stated above, in the plan view of semiconductor device 1, first electrode 61 need not be at least partially contained within second square region 42, third square region 43, and fourth square region 44.

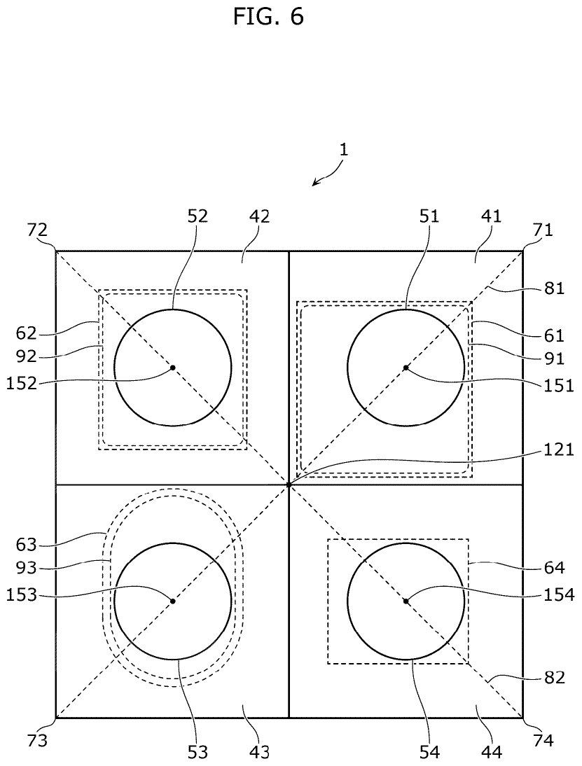

FIG. 6 is a planar schematic diagram showing another example of a structure of semiconductor device 1.

As shown in FIG. 6, for example, in the plan view of semiconductor device 1, first electrode 61 may be entirely contained within first square region 41.

### Variation 1

The following describes a semiconductor device according to Variation 1 configured by replacing first electrode 61, second electrode 62, third electrode 63, and fourth electrode 64 in semiconductor device 1 according to the present embodiment with a first electrode, a second electrode, a third electrode, and a fourth electrode according to Variation 1, respectively, and replacing source contact region 91, ohmic contact region 92, and Schottky contact region 93 in semiconductor device 1 according to the present embodiment with a source contact region, an ohmic contact region, and a Schottky contact region according to Variation 1, respectively.

Hereinafter, since constituent elements of the semiconductor device according to Variation 1 identical to those of semiconductor device 1 are already described, the same reference signs are assigned to them, the detailed description thereof is omitted, and the differences from semiconductor device 1 are mainly described.

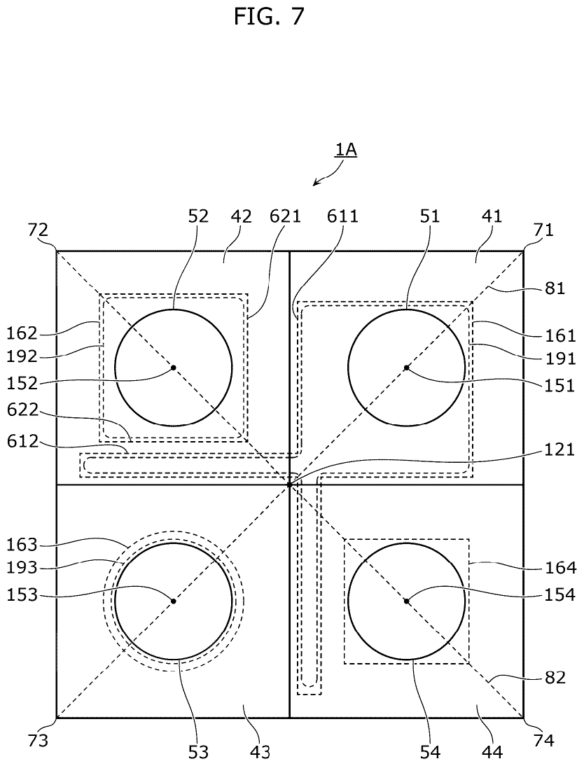

FIG. 7 is a planar schematic diagram showing an example of a structure of semiconductor device 1A according to Variation 1.

As shown in FIG. 7, semiconductor device 1A is configured by replacing first electrode 61, second electrode 62, third electrode 63, and fourth electrode 64 in semiconductor device 1 according to the present embodiment with first electrode 161, second electrode 162, third electrode 163, and fourth electrode 164, respectively, and replacing source contact region 91, ohmic contact region 92, and Schottky contact region 93 in semiconductor device 1 according to the present embodiment with source contact region 191, ohmic contact region 192, and Schottky contact region 193, respectively.

As with FIG. 1, in FIG. 7, first electrode 161, second electrode 162, third electrode 163, fourth electrode 164, source contact region 191, ohmic contact region 192, and Schottky contact region 193 are shown by dashed lines as if these electrodes and regions could be visually recognized from the outside of semiconductor device 1A; but actually these electrodes and regions cannot be visually recognized directly from the outside of semiconductor device 1A.

As shown in FIG. 7, in a plan view of semiconductor device 1A, a portion of first electrode 161 is contained within first square region 41, another portion of first electrode 161 is further contained within second square region 42 to protrude between second electrode 162 and third electrode 163, and still another portion of first electrode 161 is further contained within fourth square region 44 to protrude between third electrode 163 and fourth electrode 164.

Moreover, concomitantly, in the plan view of semiconductor device 1A, a portion of source contact region 191 is contained within first square region 41, another portion of source contact region 191 is further contained within second square region 42 to protrude between second electrode 162 and third electrode 163, and still another portion of source contact region 191 is further contained within fourth square region 44 to protrude between third electrode 163 and fourth electrode 164.

Furthermore, as shown in FIG. 7, in the plan view of semiconductor device 1A, at least a portion of second electrode 162, at least a portion of third electrode 163, and at least a portion of fourth electrode 164 are not contained within first square region 41.

With the above configuration, semiconductor device 1A makes it possible to relatively enlarge an active region that is a region entirely containing a portion of vertical MOS transistor 10 in which a channel is formed when a voltage greater than or equal to a threshold value is applied to gate conductor 15. For this reason, semiconductor device 1A makes it possible to relatively reduce the conduction resistance of vertical MOS transistor 10.

Moreover, as shown in FIG. 7, in the plan view of semiconductor device 1A, second electrode 162 is a rectangle including first opposite side 621 and second opposite side 622, first opposite side 621 including a portion parallel and opposite to first portion 611 of a peripheral side of first electrode 161, second opposite side 622 including a portion parallel and opposite to second portion 612 of the peripheral side of first electrode 161.

With the above configuration, semiconductor device 1A makes it possible to relatively increase the length of a boundary between first electrode 161 functioning as the source electrode of vertical MOS transistor 10 and second electrode 162 functioning as the drain electrode of vertical MOS transistor 10. For this reason, semiconductor device 1A makes it possible to relatively reduce the conduction resistance of vertical MOS transistor 10.

### Variation 2

The following describes a semiconductor device according to Variation 2 configured by (i) replacing first electrode 161, second electrode 162, third electrode 163, and fourth electrode 164 in semiconductor device 1A according to Variation 1 with a first electrode, a second electrode, a third electrode, and a fourth electrode according to Variation 2, respectively, to cause (a) a portion of first electrode 161 to protrude between third electrode 163 and fourth electrode 164 and (b) another portion of first electrode 161 not to protrude between second electrode 162 and third electrode 163, and cause (a) a portion of source contact region 191 to protrude between third electrode 163 and fourth electrode 164 and (b) another portion of source contact region 191 not to protrude between second electrode 162 and third electrode 163 in the plan view of semiconductor device 1A, and (ii) replacing source contact region 191, ohmic contact region 192, and Schottky contact region 193 in semiconductor device 1A according to Variation 1 with a source contact region, an ohmic contact region, and a Schottky contact region according to Variation 2, respectively.

Hereinafter, since constituent elements of the semiconductor device according to Variation 2 identical to those of semiconductor device 1A are already described, the same reference signs are assigned to them, the detailed description thereof is omitted, and the differences from semiconductor device 1A are mainly described.

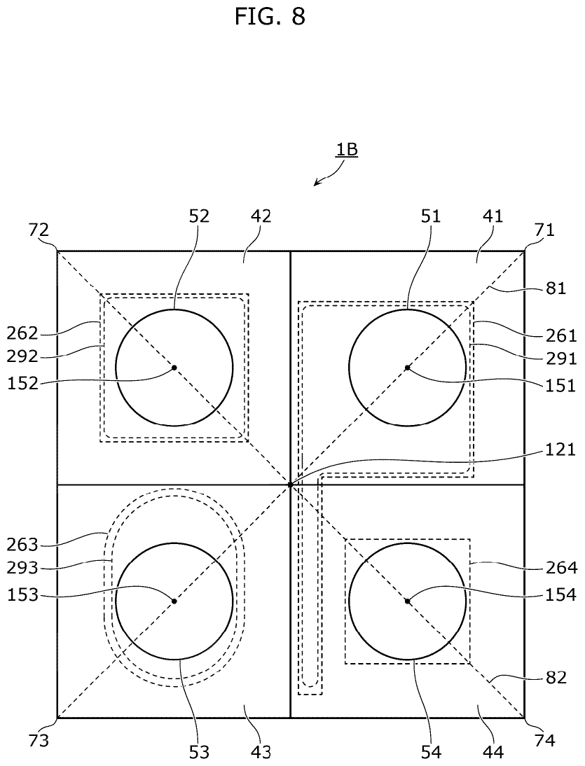

FIG. 8 is a planar schematic diagram showing an example of a structure of semiconductor device 1B according to Variation 2.

As shown in FIG. 8, semiconductor device 1B is configured by replacing first electrode 161, second electrode 162, third electrode 163, and fourth electrode 164 in semiconductor device 1A according to Variation 1 with first electrode 261, second electrode 262, third electrode 263, and fourth electrode 264, respectively, and replacing source contact region 191, ohmic contact region 192, and Schottky contact region 193 in semiconductor device 1A according to Variation 1 with source contact region 291, ohmic contact region 292, and Schottky contact region 293, respectively.

As with FIG. 1 and FIG. 7, in FIG. 8, first electrode 261, second electrode 262, third electrode 263, fourth electrode 264, source contact region 291, ohmic contact region 292, and Schottky contact region 293 are shown by dashed lines as if these electrodes and regions could be visually recognized from the outside of semiconductor device 1B; but actually these electrodes and regions cannot be visually recognized directly from the outside of semiconductor device 1B.

As shown in FIG. 8, in a plan view of semiconductor device 1B, a portion of first electrode 261 is contained within first square region 41, and another portion of first electrode 261 is further contained within fourth square region 44 to protrude between third electrode 263 and fourth electrode 264. On the other hand, first electrode 261 includes no portions that protrude between second electrode 262 and third electrode 263.

Additionally, concomitantly, in the plan view of semiconductor device 1B, a portion of source contact region 291 is contained within first square region 41, and another portion of source contact region 291 is further contained within fourth square region 44 to protrude between third electrode 263 and fourth electrode 264. On the other hand, source contact region 291 includes no portions that protrude between second electrode 262 and third electrode 263.

Unlike semiconductor device 1A according to Variation 1, in semiconductor device 1B thus configured, first electrode 261 that functions as a source electrode of vertical MOS transistor 10 is not interposed between second electrode 262 that functions as a cathode electrode of Schottky barrier diode 20 and third electrode 263 that functions as an anode electrode of Schottky barrier diode 20.

Accordingly, semiconductor device 1B thus configured makes it possible to reduce the degradation of the characteristics of Schottky barrier diode 20.

### Supplement

Although the semiconductor device according to one aspect of the present disclosure is described above based on the embodiment, Variation 1, and Variation 2, the present disclosure is not limited to the embodiment, Variation 1, and Variation 2. Forms obtained by various modifications to the embodiment, Variation 1, or Variation 2 that can be conceived by a person skilled in the art may be included in one or more aspects of the present disclosure, as long as they do not depart from the essence of the present disclosure.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### Industrial Applicability

The present disclosure is broadly applicable to semiconductor devices.

1. A semiconductor device that is a chip-size-package type semiconductor device, the semiconductor device comprising:
a semiconductor layer that includes a semiconductor substrate of a first conductivity type and a low-concentration impurity layer of the first conductivity type, the semiconductor substrate containing an impurity having a first concentration, the low-concentration impurity layer being provided on an upper surface of the semiconductor substrate and containing an impurity having a second concentration lower than the first concentration;
a vertical metal-oxide-semiconductor (MOS) transistor that is provided in the semiconductor layer; and
a Schottky barrier diode in which the low-concentration impurity layer functions as a cathode when the first conductivity type is N type, and functions as an anode when the first conductivity type is P type,
wherein the semiconductor device further comprises:
a first pad that is a portion of an upper surface of the semiconductor device and functions as a source pad of the vertical MOS transistor;
a second pad that is a portion of the upper surface of the semiconductor device, functions as a drain pad of the vertical MOS transistor, functions as a cathode pad of the Schottky barrier diode when the first conductivity type is the N type, and functions as an anode pad of the Schottky barrier diode when the first conductivity type is the P type;
a third pad that is a portion of the upper surface of the semiconductor device, functions as the anode pad of the Schottky barrier diode when the first conductivity type is the N type, and functions as the cathode pad of the Schottky barrier diode when the first conductivity type is the P type; and
a fourth pad that is a portion of the upper surface of the semiconductor device and functions as a gate pad of the vertical MOS transistor, and
in a plan view of the semiconductor device:
the semiconductor device is a square including a first vertex, a second vertex, a third vertex, and a fourth vertex in a counterclockwise direction;
the first pad, the second pad, the third pad, and the fourth pad are circles each having an equal diameter;
a center of the first pad and a center of the third pad are located on a first diagonal line connecting the first vertex and the third vertex;
a center of the second pad and a center of the fourth pad are located on a second diagonal line connecting the second vertex and the fourth vertex; and
a distance between a center of the semiconductor device and the center of the first pad, a distance between the center of the semiconductor device and the center of the second pad, a distance between the center of the semiconductor device and the center of the third pad, and a distance between the center of the semiconductor device and the center of the fourth pad are equal.

2. The semiconductor device according to claim 1,
wherein in the plan view of the semiconductor device, when an area of the semiconductor device is equally divided by four square regions that do not overlap each other, the four square regions being a first square region having a line connecting the first vertex and the center of the semiconductor device as a diagonal line, a second square region having a line connecting the second vertex and the center of the semiconductor device as a diagonal line, a third square region having a line connecting the third vertex and the center of the semiconductor device as a diagonal line, and a fourth square region having a line connecting the fourth vertex and the center of the semiconductor device as a diagonal line:
the first pad is contained within the first square region;
the second pad is contained within a second-pad-containing square region that is one of the second square region or the fourth square region;
the third pad is contained within the third square region; and
the fourth pad is contained within a fourth-pad-containing square region that is an other of the second square region or the fourth square region,
the semiconductor layer further includes a drain lead-out region of the first conductivity type, the drain lead-out region being entirely contained within the second-pad-containing square region in a plan view of the semiconductor layer, penetrating through the low-concentration impurity layer from an upper surface of the semiconductor layer to the semiconductor substrate, and containing an impurity having a third concentration higher than the second concentration, and
in the plan view of the semiconductor device, the semiconductor device further comprises:
a first electrode that is at least partially contained within the first square region and functions as a source electrode of the vertical MOS transistor;
a second electrode that is at least partially contained within the second-pad-containing square region, functions as a drain electrode of the vertical MOS transistor, functions as a cathode electrode of the Schottky barrier diode when the first conductivity type is the N type, and functions as an anode electrode of the Schottky barrier diode when the first conductivity type is the P type;
a third electrode that is at least partially contained within the third square region, functions as the anode electrode of the Schottky barrier diode when the first conductivity type is the N type, and functions as the cathode electrode of the Schottky barrier diode when the first conductivity type is the P type; and
a fourth electrode that is at least partially contained within the fourth-pad-containing square region and functions as a gate electrode of the vertical MOS transistor.

3. The semiconductor device according to claim 2,
wherein the Schottky barrier diode is of a planar type.

4. The semiconductor device according to claim 2,
wherein the second electrode includes a plurality of metal layers including an ohmic contact metal layer that is in ohmic contact with the drain lead-out region,
the third electrode includes a plurality of metal layers including a Schottky contact metal layer that is in Schottky contact with the low-concentration impurity layer, and
a metal material of the ohmic contact metal layer is identical to a metal material of the Schottky contact metal layer.

5. The semiconductor device according to claim 2,
wherein the second electrode includes a plurality of metal layers including an ohmic contact metal layer that is in ohmic contact with the drain lead-out region,
the third electrode includes a plurality of metal layers including a Schottky contact metal layer that is in Schottky contact with the low-concentration impurity layer, and
a metal material of the ohmic contact metal layer is different from a metal material of the Schottky contact metal layer.

6. The semiconductor device according to claim 2,
wherein in the plan view of the semiconductor device:
the first electrode is at least partially contained within at least one of the second-pad-containing square region or the fourth-pad-containing square region, and
at least a portion of the second electrode, at least a portion of the third electrode, and at least a portion of the fourth electrode are not contained within the first square region.

7. The semiconductor device according to claim 6,
wherein in the plan view of the semiconductor device, the second electrode is a rectangle including a first opposite side and a second opposite side, the first opposite side including a portion parallel and opposite to a first portion of a peripheral side of the first electrode, the second opposite side including a portion parallel and opposite to a second portion of the peripheral side of the first electrode.

8. The semiconductor device according to claim 6,
wherein in the plan view of the semiconductor device, at least a portion of the first electrode is not contained within the second-pad-containing square region.

9. The semiconductor device according to claim 2,
wherein the third electrode and the low-concentration impurity layer are in Schottky contact in a Schottky contact region,
the second electrode and the drain lead-out region are in ohmic contact in an ohmic contact region,
the first electrode and the semiconductor layer are in contact with each other in a source contact region, and
in the plan view of the semiconductor device:
the Schottky contact region is contained within the third electrode and is one of a circle, an ellipse, an oblong, or a rounded-corner rectangle obtained by rounding off each of corners of a rectangle; and
a shortest distance between the Schottky contact region and the ohmic contact region is less than a shortest distance between the Schottky contact region and the source contact region.

10. The semiconductor device according to claim 9,
wherein in the plan view of the semiconductor device, an area of the Schottky contact region is larger than an area of the third pad.

11. The semiconductor device according to claim 9,
wherein in the plan view of the semiconductor device, an area of the Schottky contact region is smaller than an area of the third pad.

12. The semiconductor device according to claim 2,
wherein the third electrode and the low-concentration impurity layer are in Schottky contact in a Schottky contact region,
the first electrode and the semiconductor layer are in contact with each other in a source contact region, and
in the plan view of the semiconductor device:
the Schottky contact region is one of a circle, an ellipse, an oblong, or a rounded-corner rectangle obtained by rounding off each of corners of a rectangle;
the source contact region is a rounded-corner rectangle obtained by rounding off each of corners of a polygon; and
a minimum curvature radius in a periphery of the Schottky contact region is greater than or equal to a minimum curvature radius in the source contact region.
